(19) United States
(12) Patent Application Publication
(10) Pub. No.: US 2019/0273319 A1
(43) Pub. Date: Sep. 5, 2019

(54) ANTENNA AND SIGNAL INPUT CIRCUIT THEREOF

(71) Applicants: INVENTEC (PUDONG) TECHNOLOGY CORPORATION, Shanghai City (CN); INVENTEC CORPORATION, Taipei City (TW)

(72) Inventors: Ssu Han TING, Taipei City (TW); Chih-Cheng LI, Taipei City (TW)

(73) Assignees: INVENTEC (PUDONG) TECHNOLOGY CORPORATION, Shanghai City (CN); INVENTEC CORPORATION, Taipei City (TW)

(21) Appl. No.: 16/188,822

(22) Filed: Nov. 13, 2018

(30) Foreign Application Priority Data
Mar. 2, 2018 (CN) 201810173616.7

(51) Int. Cl. H01Q 5/335; H03H 7/38; H04B 1/18

(52) U.S. Cl. CPC H01Q 5/335; H04B 1/18; H03H 7/38

(57) ABSTRACT

A signal input circuit applied to an antenna comprises a balun transformer and a regulation circuit. The balun transformer has one first signal input terminal and two first signal output terminals. The balun transformer receives a feed signal and a ground signal via the first signal input terminal, generates two balanced signals based on the feed signal and the ground signal, and respectively outputs the two balanced signals via the two first signal output terminals. The regulation circuit is configured to adjust the two balanced signals into adjusted signals and has two second signal input terminals and two second signal output terminals, with the two second signal input terminals respectively connected with the two first signal output terminals of the balun transformer, and the two second signal output terminals configured to respectively output the two adjusted signals to an emitting portion of the antenna.

### CROSS-REFERENCE TO RELATED APPLICATIONS

This non-provisional application claims priority under 35 U.S.C. § 119(a) on Patent Application No(s). 201810173616.7 filed in China on Mar. 2, 2018, the entire contents of which are hereby incorporated by reference.

### BACKGROUND

### Technical Field

This disclosure relates to a signal input circuit, and particularly to a signal input circuit applied to an antenna.

### Related Art

In a wireless communication system, an antenna serves as an intermediary between a transceiver and the transmission environment, and has the functions of converting voltage, current and electromagnetic field signals and changing the distribution of electromagnetic waves in space. With the development of wireless communication technology and the change of modern lifestyles, the demand for development of various types of mobile wireless communication products is dramatically increased in the current wireless communication industry.

Therefore, for developing various and new wireless communication specifications and products, the development of an antenna which is a key element in the wireless communication technology is increasingly important.

### SUMMARY

This disclosure provides an antenna and a signal input circuit thereof.

According to an embodiment of this disclosure, a signal input circuit applied to an antenna comprises a balun transformer and a regulation circuit. The balun transformer has one first signal input terminal and two first signal output terminals. The balun transformer receives a feed signal and a ground signal via the first signal input terminal, generates two balanced signals based on the feed signal and the ground signal, and respectively outputs the two balanced signals via the two first signal output terminals. The regulation circuit is configured to adjust the two balanced signals into two adjusted signals and has two second signal input terminals and two second signal output terminals, with the two second signal input terminals respectively connected with the two first signal output terminals of the balun transformer, and the two second signal output terminals configured to respectively output the two adjusted signals to an emitting portion of the antenna.

According to an embodiment of this disclosure, an antenna comprises a first emitting portion, a second emitting portion, a balun transformer and a regulation circuit. The first emitting portion has a first bending side edge and a first feed position, and the second emitting portion has a second bending side edge and a second feed position. A tapered slot is formed between the second bending side edge and the first bending side edge, wherein the tapered slot comprises a necking end and a flaring end. The balun transformer has one first signal input terminal and two first signal output terminals. The balun transformer receives a feed signal and a ground signal via the first signal input terminal, generates two balanced signals based on the feed signal and the ground signal, and respectively outputs the two balanced signals via the two first signal output terminals. The regulation circuit is configured to adjust the two balanced signals into two adjusted signals and has two second signal input terminals and two second signal output terminals, with the two second signal input terminals respectively connected with the two first signal output terminals of the balun transformer, and the two second signal output terminals respectively connected with the first feed position and the second feed position to respectively output the two adjusted signals to the first emitting portion and the second emitting portion of the antenna.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a function block diagram of a signal input circuit applied to an antenna according to an embodiment of this disclosure;

FIG. 2 is a schematic diagram of a signal input circuit applied to an antenna according to an embodiment of this disclosure;

FIG. 3 is a schematic diagram of an antenna according to an embodiment of this disclosure;

FIG. 4A is a schematic diagram of the disposition of an antenna according to an embodiment of this disclosure; and

FIG. 4B is a schematic diagram of the disposition of an antenna according to another embodiment of this disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

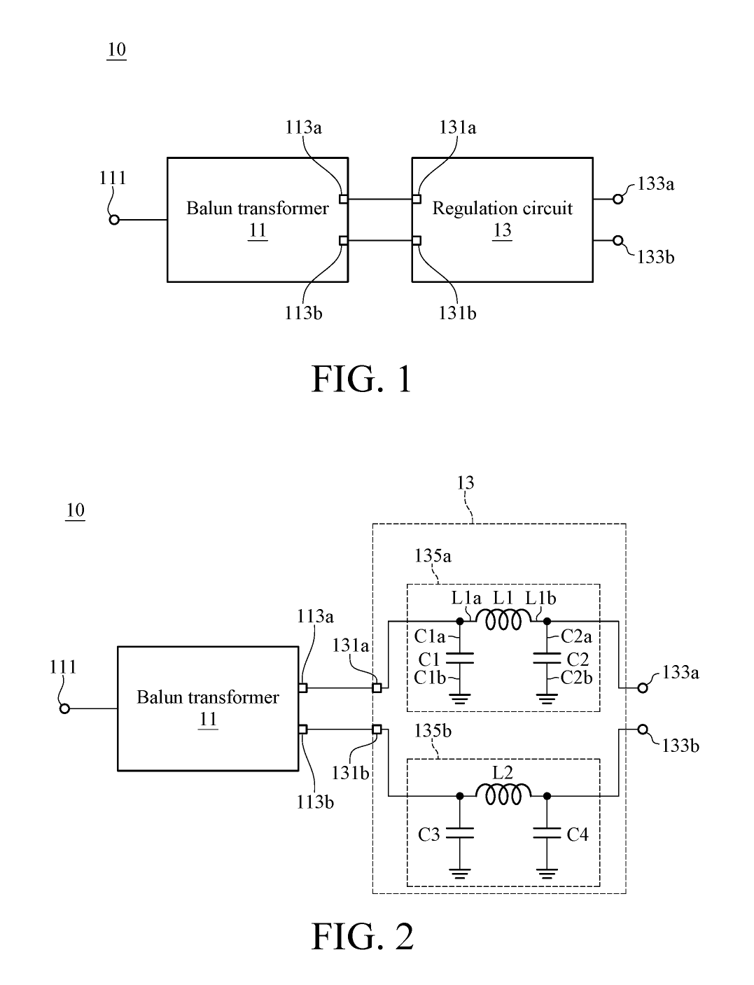

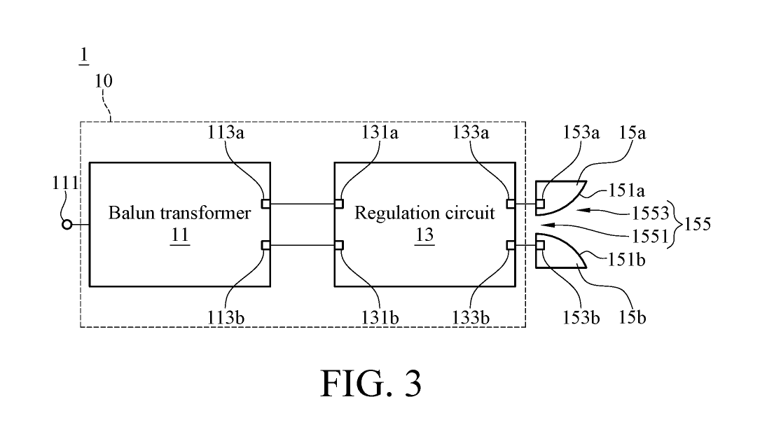

Please refer to FIG. 1 and FIG. 2, wherein FIG. 1 is a function block diagram of a signal input circuit applied to an antenna according to an embodiment of this disclosure, and FIG. 2 is a schematic diagram of a signal input circuit applied to an antenna according to an embodiment of this disclosure. In the embodiment as shown in FIG. 1, a signal input circuit 10 is applied to an antenna, and configured to convert and adjust external signals and then input them to the emitting portion of the antenna. More specifically, the signal input circuit 10 is applied to any portable electronic device having an antenna, such as a tablet computer, a notebook computer, etc.

As shown in FIG. 1, the signal input circuit 10 comprises a balun transformer 11 and a regulation circuit 13. The balun transformer 11, such as a balanced-to-unbalanced transformer, has one first signal input terminal 111 and two first signal output terminals 113a and 113b. The first signal input terminal 111 is configured to receive a feed signal and a ground signal. More specifically, the first signal input terminal 111 can be electrically connected with a coaxial cable. The coaxial cable comprises at least a conducting wire, an insulation layer coating the conducting wire, and a conductive layer outside the insulation layer, wherein the conducting wire transmits the feed signal to the balun transformer 11, and the conductive layer transmits the ground signal to the balun transformer 11. The balun transformer 11 generates two balanced signals based on the feed signal and the ground signal from the coaxial cable, and outputs these two balanced signals respectively via the first signal output terminals 113a and 113b. More specifically, these two balanced signals have the same amplitude but their phases differ by 180 degrees.

The regulation circuit 13 has two second signal input terminals 131a and 131b and two second signal output terminals 133a and 133b, wherein the second signal input terminals 131a and 131b are electrically connected with the first signal output terminals 113a and 113b of the balun transformer 11 respectively for receiving and adjusting the two balanced signals into two adjusted signals, and then the regulation circuit 13 outputs the adjusted signals via the second signal output terminals 133a and 133b to the emitting portion of the antenna.

In particular, as shown in FIG. 2, the regulation circuit 13 comprises two impedance matching circuits 135a and 135b for performing the impedance matching of the antenna. Each of the impedance matching circuits 135a and 135b comprises an inductor, a first capacitor and a second capacitor. More specifically, the impedance matching circuit 135a comprises an inductor L1, a first capacitor C1 and a second capacitor C2, wherein the first terminal L1a and second terminal L1b of the inductor L1 are electrically connected with the second signal input terminals 131a and the second signal output terminals 133a respectively; the first terminal C1a and the second terminal C1b of the first capacitor C1 are electrically connected with the first terminal L1a of the inductor L1 and a ground terminal respectively; and the first terminal C2a and the second terminal C2b of the second capacitor C2 are electrically connected with the second terminal L1b of the inductor L1 and the ground terminal respectively. The inductor L1, the first capacitor C1 and the second capacitor C2 of the impedance matching circuit 135a form a π-shaped circuit together; and the impedance matching circuit 135b also comprises a inductor L2, a first capacitor C3 and a second capacitor C4 to form another π-shaped circuit together, wherein the connections between the above terminals and components are similar to those of the aforementioned impedance matching circuit 135a, so the related details are not repeated. The impedance matching circuits 135a and 135b of the regulation circuit 13 are configured to match the characteristic impedance of the signal end with the impedance of the load end of the antenna. In other words, the regulation circuit 13 can match the characteristic impedance of the side connected with the balun transformer 11 with the loading impedance of the side connected with the emitting portion of the antenna.

In another embodiment, the regulation circuit 13 can also be configured to adjust the phase difference between the two balanced signals as aforementioned so that the antenna can generate various electromagnetic waves with different wave velocities or directivities. More specifically, the regulation circuit 13 can comprise an integrated circuit or a microstrip line for adjusting the phase difference between the two balanced signals. In yet another embodiment, the integrated circuit or the microstrip line for adjusting the phase difference can be disposed in the circuit of the balun transformer 11.

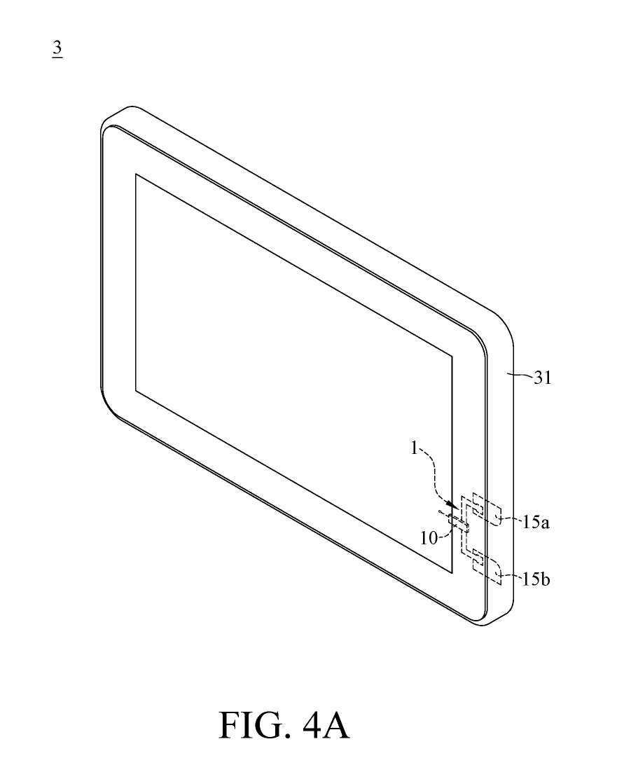

Please refer to FIG. 3 which is a schematic diagram of an antenna according to an embodiment of this disclosure. As shown in FIG. 3, an antenna 1 comprises a balun transformer 11, a regulation circuit 13, a first emitting portion 15a and a second emitting portion 15b, wherein the group of the balun transformer 11 and the regulation circuit 13 is the signal input circuit 10 as described in the above embodiment, so that the detailed circuit structures and functions thereof are not repeated herein.

In this embodiment, the first emitting portion 15a and the second emitting portion 15b are metallic sheet structures for example. The first emitting portion 15a has a first bending side edge 151a and a first feed position 153a, and the second emitting portion 15b has a second bending side edge 151b and a second feed position 153b, wherein a tapered slot 155 comprising a necking end 1551 and a flaring end 1553 is formed between the first bending side edge 151a of the first emitting portion 15a and the second bending side edge 151b of the second emitting portion 15b. More specifically, the first bending side edge 151a and the second bending side edge 151b can respectively be two convex arcs, and these two convex arcs are oppositely disposed to form the tapered slot 155. Moreover, the first bending side edge 151a the second bending side edge 151b can also be side edges having a number of bending portions. The signal input circuit 10 in this disclosure is not limited to be combined with the antenna emitting portion having the aforementioned structure to form the antenna 1.

In the details of the process of generating and outputting an electromagnetic wave by the antenna 1 in the above embodiment, the balun transformer 11 simultaneously receives the feed signal and the ground signal from the coaxial cable so as to generate two balanced signals; then, the balun transformer 11 outputs the two balanced signals to the regulation circuit 13 respectively via the two first signal output terminals 113a and 113b; the regulation circuit 13 adjusts the two balanced signals into two adjusted signals and then transmits the two adjusted signals to the first emitting portion 15a and the second emitting portion 15b respectively; then, the first emitting portion 15a and the second emitting portion 15b generate the electromagnetic wave based on the received signals, and the electromagnetic wave is outputted through the tapered slot 155. In particular, the tapered structure between the necking end 1551 and the flaring end 1553 of the tapered slot 155 is similar to the structure of a Vivaldi antenna.

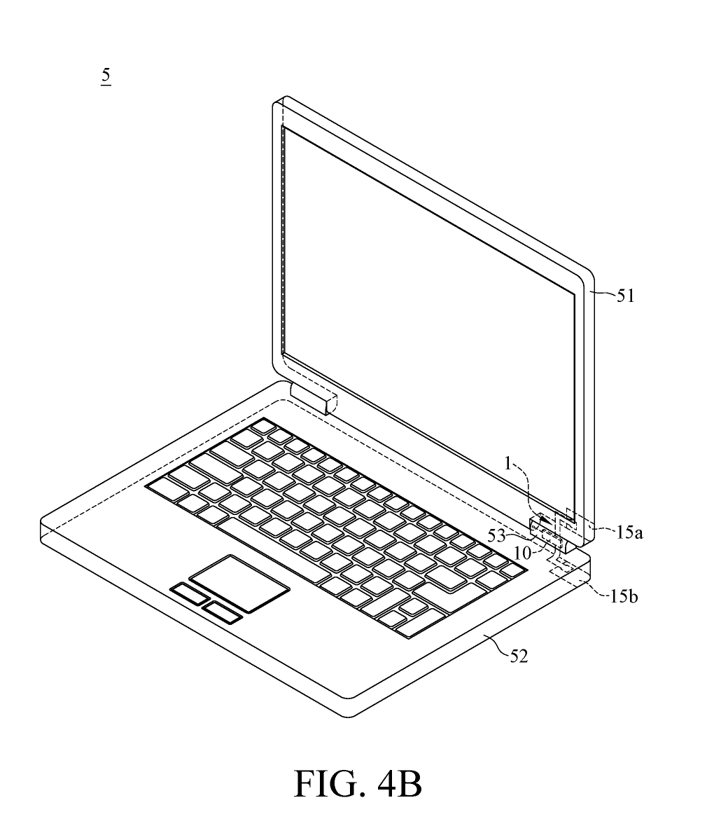

Please refer to FIG. 3, FIG. 4A and FIG. 4B, wherein FIG. 4A is a schematic diagram of the disposition of an antenna according to an embodiment of this disclosure, and FIG. 4B is a schematic diagram of the disposition of an antenna according to another embodiment of this disclosure. The antenna 1 described in the above embodiments is applied to a portable electronic device, such as a tablet computer, a notebook computer or other portable electronic device. In the embodiment as shown in FIG. 4A, the antenna 1 can be disposed in the tablet computer 3, wherein the first emitting portion 15a and the second emitting portion 15b of the antenna 1 can be disposed together on the surface layer or interlayer of the casing 31 of the tablet computer 3, or be disposed respectively on different layers. As shown in FIG. 4B, the antenna 1 can also be disposed in the notebook computer 5. In this embodiment, the first emitting portion 15a and the second emitting portion 15b are respectively disposed at the corner of the two casings 51 and 52 (e.g. upper lid and bottom base) of the notebook computer 5.

FIGS. 4A and 4B exemplary illustrate the setting position of the antenna 1. However, in another embodiment, the first emitting portion 15a and the second emitting portion 15b of the antenna 1 can also be can also be disposed together on the outside of the upper lid of the notebook computer 5, between the outside and the inside (i.e. the side where the screen is disposed) of the upper lid, on the outside of the bottom base of the notebook computer 5, between the outside and the inside (i.e. the side where the keyboard is disposed) of the bottom base or on the inside of the bottom base, or be respectively disposed in two of the above setting positions. Moreover, in the embodiment of FIG. 4B, the signal input circuit 10 of the antenna 1 is disposed in the hinge 53 of the notebook computer 5. In another embodiment, the signal input circuit 10 can also be disposed at the upper lid or the bottom base of the notebook computer 5. Moreover, the balun transformer 11 and the regulation circuit 13 of the signal input circuit 10 can also be disposed respectively at two of the upper lid, hinge 53 and the bottom base of the notebook computer 5. In addition to the aforementioned tablet computer 3 and notebook computer 5, the antenna 1 can also be disposed in any portable electronic device with the function of an antenna, which is not limited in this disclosure.

In view of the above description, the signal input circuit and the antenna with the signal input circuit in this disclosure provides a signal input mechanism performed by a balun transformer and a regulation circuit, so as to reduce the difficulty in the design of the emitting portion of the antenna, and to improve the disposition flexibility of the antenna in an electronic device.

What is claimed is:

1. A signal input circuit applied to an antenna, and comprising:
a balun transformer having one first signal input terminal and two first signal output terminals, receiving a feed signal and a ground signal via the first signal input terminal, generating two balanced signals based on the feed signal and the ground signal, and respectively outputting the two balanced signals via the two first signal output terminals; and
a regulation circuit, configured to adjust the two balanced signals into two adjusted signals, having two second signal input terminals and two second signal output terminals, with the two second signal input terminals respectively connected with the two first signal output terminals of the balun transformer, and the two second signal output terminals configured to respectively output the two adjusted signals to an emitting portion of the antenna.

2. The signal input circuit according to claim 1, wherein the regulation circuit comprises two impedance matching circuits configured to perform impedance matching of the antenna.

3. The signal input circuit according to claim 2, wherein each of the two impedance matching circuits comprises an inductor, a first capacitor and a second capacitor, the inductor has a first terminal and a second terminal which are respectively connected with one of the two second signal input terminals and one of the two second signal output terminals, two terminals of the first capacitor are respectively connected with the first terminal of the inductor and a ground terminal, and two terminals of the second capacitor are respectively connected with the second terminal of the inductor and the ground terminal.

4. The signal input circuit according to claim 1, wherein the regulation circuit adjusts a phase difference between the two balanced signals.

5. An antenna, comprising:
a first emitting portion having a first bending side edge and a first feed position;
a second emitting portion having a second bending side edge and a second feed position, wherein a tapered slot is formed between the second bending side edge and the first bending side edge and comprises a necking end and a flaring end;
a balun transformer, having one first signal input terminal and two first signal output terminals, and receiving a feed signal and a ground signal via the first signal input terminal, generating two balanced signals based on the feed signal and the ground signal, and respectively outputting the two balanced signals via the two first signal output terminals; and
a regulation circuit, configured to adjust the two balanced signals into two adjusted signals, having two second signal input terminals and two second signal output terminals, with the two second signal input terminals respectively connected with the two first signal output terminals of the balun transformer, and the two second signal output terminals respectively connected with the first feed position and the second feed position to respectively output the two adjusted signals to the first emitting portion and the second emitting portion of the antenna.

6. The antenna according to claim 5, wherein the first bending side edge and the second bending side edge respectively have two convex arcs, and the two convex arcs are oppositely disposed to form the tapered slot.

7. The antenna according to claim 5, wherein the regulation circuit comprises two impedance matching circuits configured to perform impedance matching of the antenna.

8. The antenna according to claim 7, wherein each of the two impedance matching circuits comprises an inductor, a first capacitor and a second capacitor, the inductor has a first terminal and a second terminal which are respectively connected with one of the two second signal input terminals and one of the two second signal output terminals, two terminals of the first capacitor are respectively connected with the first terminal of the inductor and a ground terminal, and two terminals of the second capacitor are respectively connected with the second terminal of the inductor and the ground terminal.

9. The antenna according to claim 5, wherein the regulation circuit is configured to adjust a phase difference between the two balanced signals.

10. The antenna according to claim 5, wherein the antenna is applied to a portable electronic device with a casing, and the first emitting portion and the second emitting portion of the antenna are disposed at the casing of the portable electronic device.

11. The antenna according to claim 5, wherein the antenna is applied to a portable electronic device with two casings, and the first emitting portion and the second emitting portion of the antenna are respectively disposed at the two casings of the portable electronic device.
